(19) United States
(12) Patent Application Publication
(10) Pub. No.: US 2026/0156848 A1
(43) Pub. Date: Jun. 4, 2026

(54) MULTI-KV-CLASS GALLIUM NITRIDE POWER DEVICES WITH HYDROGEN PLASMA GUARD ARRAY TERMINATION

(71) Applicants: Houqiang Fu, Chandler, AZ (US); Dawei Wang, Tempe, AZ (US); Dinusha Herath Mudiyanselage, Mesa, AZ (US)

(72) Inventors: Houqiang Fu, Chandler, AZ (US); Dawei Wang, Tempe, AZ (US); Dinusha Herath Mudiyanselage, Mesa, AZ (US)

(21) Appl. No.: 19/405,960

(22) Filed: Dec. 2, 2025

Related U.S. Application Data
(60) Provisional application No. 63/726,713, filed on Dec. 2, 2024.

(51) Int. Cl. H10D 8/60; H10D 8/01; H10D 62/824; H10D 64/23

(52) U.S. Cl. CPC H10D 8/60; H10D 8/051; H10D 8/053; H10D 62/824; H10D 64/23

(57) ABSTRACT

A Schottky barrier diode includes a SiC substrate, a GaN buffer layer, a first unintentionally doped GaN layer, an AlN layer, an AlGaN layer, a second unintentionally doped GaN layer, a p-GaN layer doped with Mg, and a cathode and an anode, each in direct contact with the first unintentionally doped GaN layer, the AlN layer, the AlGaN layer, the second unintentionally doped GaN layer, and the p-GaN layer. The anode has a length L_{A} along the p-GaN layer, the cathode has a length L_{C} along the p-GaN layer, and the anode and the cathode are separated by a distance L_{AC}. An outer surface of the p-GaN layer defines n portions, each portion having a length L_{Tn} extending along the p-GaN layer between the cathode and the anode and defining an array Tₙ of activated p-GaN regions. Each element in array Tₙ is separated by a passivated p-GaN region.

### CROSS-REFERENCE TO RELATED APPLICATION

This application claims the benefit of U.S. patent application Ser. No. 63/726,713 filed on

Dec. 2, 2024, which is incorporated by reference herein in its entirety.

### STATEMENT OF GOVERNMENT SUPPORT

This invention was made with government support under 2302696 awarded by the National Science Foundation. The government has certain rights in the invention.

### TECHNICAL FIELD

This invention relates to a hydrogen plasma-based guard array termination (H-GAT) design for a multi-kV-class aluminum gallium nitride (AlGaN)/gallium nitride (GaN) heterojunction Schottky barrier diodes.

### BACKGROUND

Multi-kV aluminum gallium nitride (AlGaN)/gallium nitride (GaN) heterojunction Schottky barrier diodes are generally more complex than low-voltage diodes with respect to device structures, passivation, field plates, and terminations, with additional processing steps of mesa etchings, growth, and surface treatment in the fabrication. These fabrication processes can introduce risks in the device yield and device reliability.

### SUMMARY

This disclosure describes a hydrogen plasma-based guard array termination (H-GAT) for multi-kV aluminum gallium nitride (AlGaN)/gallium nitride (GaN) heterojunction Schottky barrier diodes. A breakdown voltage (BV) of 9.5 kV, a specific on-resistance (R_{ON}) of 97 Ω·mm, and a capacitance at zero bias (Cⱼ₀) of 4.2 pF/mm are achieved for a p-GaN/AlGaN/GaN-on-SiC platform. The fabrication process using hydrogen plasma termination is also described.

In a first general aspect, a Schottky barrier diode includes a SiC substrate, a GaN buffer layer, a first unintentionally doped GaN layer, an AlN layer, an AlGaN layer, a second unintentionally doped GaN layer, a p-GaN layer, wherein the p-GaN layer is doped with Mg, and a cathode and an anode, each in direct contact with the first unintentionally doped GaN layer, the AlN layer, the AlGaN layer, the second unintentionally doped GaN layer, and the p-GaN layer, wherein the anode has a length L_{A} along the p-GaN layer, the cathode has a length L_{C} along the p-GaN layer, and the anode and the cathode are separated by a distance L_{AC} along the p-GaN layer, wherein an outer surface of the p-GaN layer defines n portions, each portion having a length L_{Tn} extending along the p-GaN layer between the cathode and the anode and defining an array Tₙ of activated p-GaN regions, and each element in array Tₙ is separated by a passivated p-GaN region.

Implementations of the first general aspect can include one or more of the following features.

In some cases, each element in each array Tₙ is a circular element, each circular element in each array Tₙ has a diameter R_{Tn}, and each R_{Tn} is independently in a range of 0.5μm to 1 μm. In some implementations, each circular element in each array Tₙ is arranged in a row, and each row is separated from an adjacent row in array Tₙ by distance D_{Tn}. Each circular element in each array Tₙ can be separated from other circular elements in array Tₙ by distance S_{Tn}. In some cases, n=3. In some implementations, array T₁ is positioned closer to the anode, array T₃ is positioned closer to the cathode, and array T₂ is positioned between array T₁ and array T₃. Each L_{Tn} can be in a range of 10 μm to 60 μm. In some cases, L₃>L₂>L₁. Each S_{Tn} can be in a range of 0.1 μm to 5μm. In some implementations, S_{T3}>S_{T2}>S_{T1}. Each D_{Tn} can be in a range of 0.1 μm to 5 μm. In some cases, D_{T3}>D_{T2}>D_{T1}. L_{AC} can be in a range of 5 μm to 150 μm. In some cases, L_{A} is in a range of 1 μm to 15 μm. A thickness of the first unintentionally doped GaN layer can be in a range of 200 nm to 400 nm. In some implementations, a thickness of the AlN layer is in a range of about 0.1 nm to about 5 nm, a thickness of the AlGaN layer is in a range of 10 nm to 30 nm, and a thickness of the second unintentionally doped GaN layer is in a range of 1 nm to 10 nm. In some cases, a thickness of the p-GaN layer is in a range of 50 nm to 150 nm. A concentration of the Mg in the p-GaN layer can be in a range of 1×10¹⁸ to 1×10²⁰ cm⁻³. In some cases, a surface of the p-GaN layer in contact with the anode has alternating regions of activated and passivated p-GaN.

In a second general aspect, fabricating a Schottky barrier diode includes growing a plurality of epilayers by metal-organic vapor deposition on a SiC substrate in the following sequence to yield a device: a GaN buffer layer; a first unintentionally doped GaN layer; an AlN layer; an AlGaN layer; a second unintentionally doped GaN layer; and a p-GaN layer, wherein the p-GaN layer is doped with Mg, annealing the device to activate the p-GaN layer, depositing a cathode on the device, masking selected portions of the device, exposing the device to a hydrogen plasma, annealing the device, thereby bonding hydrogen atoms to at least some of the Mg, and depositing an anode on the device.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1A is a schematic of the aluminum gallium nitride (AlGaN)/gallium nitride (GaN) heterojunction Schottky barrier diode with a hydrogen plasma-based guard array termination (H-GAT). FIG. 1B is a schematic diagram of a reference sample without H-GAT design. FIG. 1C is a scanning electron microscope (SEM) image showing regions near the anode with the H-GAT region visible. FIG. 1D is an SEM image showing a region outlined in FIG. 1C.

FIG. 2A shows forward current-voltage (I-V) curves of AlGaN/GaN heterojunction Schottky barrier diodes with and without H-GAT. FIG. 2B shows calculated ideality factor and specific on-resistance (R_{ON}) of the two devices in FIG. 2A. FIG. 2C shows 100 cycles of forward and background I-V curve scans of the H-GAT device. FIG. 2D shows R_{ON} vs. L_{AC} for the devices with H-GAT. FIG. 2E shows C-V measurement at 1 MHz of the devices with and without H-GAT. FIG. 2F shows C-V measurement of the H-GAT devices of L_{AC}=120 μm with an L_{A} of 4, 8, and 12 μm at 1 MHz.

FIG. 3A shows a reverse I-V curve of the device with or without H-GAT. FIG. 3B shows breakdown measurement of the devices (L_{AC}=120 μm) with or without H-GAT. The insert is a schematic diagram of three measured devices with different termination structures. The termination structure includes T₁ (no T₂ and T₃), with a D_{T1} of 3, 2, and 1 μm, respectively. The S_{T1} is 1 μm and the L_{A} is 4 μm. FIG. 3C shows breakdown voltages of the devices of L_{AC}=120 μm. FIG. 3D shows breakdown performance of the device of L_{AC}=10 and 20 μm (with T₁ only).

FIG. 4A is a schematic of the simulated the AlGaN/GaN heterojunction Schottky barrier diodes (L_{AC}=30 μm, R_{T}=D_{T}=0.5 μm). FIG. 4B shows the electric field distribution of the device without and with floating p-GaN termination.

### DETAILED DESCRIPTION

This disclosure describes a multi-kV-class aluminum gallium nitride (AlGaN)/gallium nitride (GaN) heterojunction Schottky barrier diodes with a low capacitance at zero bias (Cⱼ₀) of 4.2 pF/mm, a specific on-resistance (R_{ON}) of 97 Ω·mm, and a Baliga's figure of merit (BFOM) of 0.79 GW/cm². A floating guard array termination structure using hydrogen plasma is described, achieving high breakdown voltage and low Cⱼ₀. A hydrogen plasma-based guard array termination (H-GAT) design includes a series of guard array structures fabricated using hydrogen plasma technology on the p-GaN for termination.

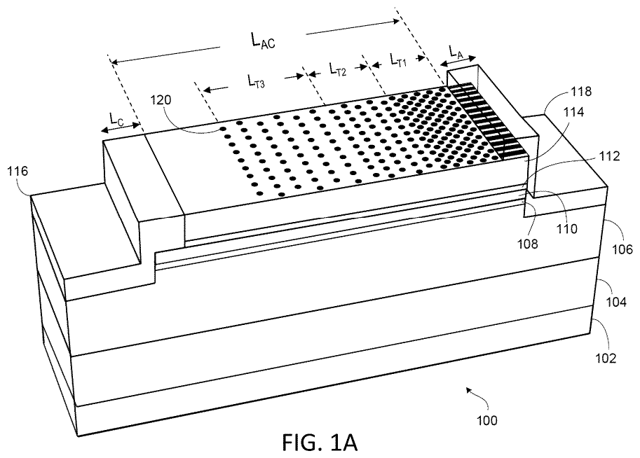

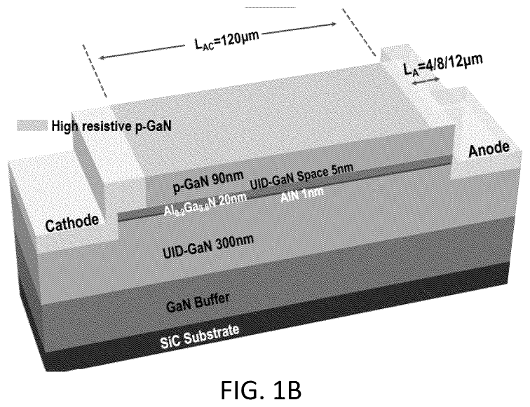

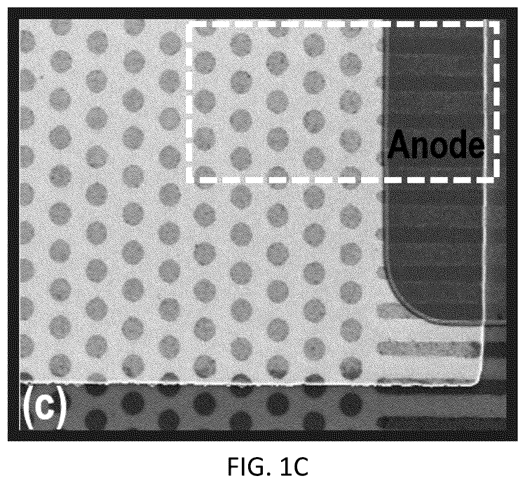

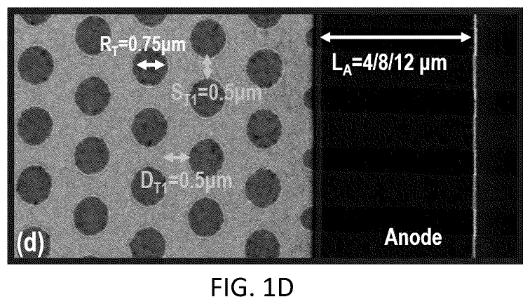

FIG. 1A is a schematic diagram of an example Schottky barrier diode 100. The Schottky barrier diode includes a SiC substrate 102, a GaN buffer layer 104, a first unintentionally doped GaN layer 106, an AlN layer 108, an AlGaN layer 110, a second unintentionally doped GaN layer 112, a p-GaN layer 114, a cathode 116, and an anode 118. In some cases, the AlGaN layer 110 includes a Al_{0.2}Ga_{0.8}N layer. The p-GaN layer 114 is doped with magnesium (Mg). The cathode 116 and anode 118 are each in direct contact with the first unintentionally doped GaN layer 106, the AlN layer 108, the second unintentionally doped GaN layer 112, and the p-GaN layer 114. The anode 118 has a length L_{A} along the p-GaN layer 114, and the cathode 116 has a length L_{C} along the p-GaN layer 114. The anode 118 and the cathode 116 are separated by a distance L_{AC} along the p-GaN layer 114. An outer surface of the p-GaN layer 114 defines n portions. Each portion has a length L_{Tn} extending along the p-GaN layer 114 between the cathode 116 and the anode 118 and defining an array Tₙ of activated p-GaN regions. Each circular element 120 in array Tₙ is separated by a passivated p-GaN region. In array T_{n,} n can be in a range of 2 to 5 (e.g., 3).

Each element 120 in each array Tₙ is a circular element and has a diameter R_{Tn}. Each R_{Tn} is typically independently in a range of 0.5 μm to 1 μm (e.g., 0.75 μm). Each circular element 120 in each array Tₙ is arranged in a row, and each row is separated from an adjacent row in array Tₙ by distance D_{Tn}. Each circular element 120 in each array Tₙ is separated from other circular elements in array Tₙ by distance S_{Tn}.

Array T₁ is typically positioned closer to the anode 118, array T₃ is typically positioned closer to the cathode 116, and array T₂ is typically positioned between array T₁ and array T₃. Each L_{Tn} is typically in a range of 10 μm to 60 μm (e.g., 24 μm, 32 μm, or 48 μm). In some cases, L₃>L₂>L₁. Each S_{Tn} is typically in a range of 0.1 μm to 5 μm (e.g., 0.5 μm, 1 μm, or 2 μm). In some implementations, S_{T3}>S_{T2}>S_{T1}. Each D_{Tn} is typically in a range of 0.1 μm to 5 μm (e.g., 0.5 μm, 1 μm, or 2 μm). In some cases, D_{T3}>D_{T2}>D_{T1}. L_{AC} is typically in a range of 5 μm to 150 μm (e.g., 10, 20, 50, or 120 μm). L_{A} is typically in a range of 1 μm to 15 μm (e.g., 4 μm, 8 μm, or 12 μm).

A thickness of the first unintentionally doped GaN layer 106 is typically in a range of 200 nm to 400 nm (e.g., 300 nm). In some cases, a thickness of the AlN layer 108 is in a range of about 0.1 nm to about 5 nm (e.g., 1 nm). In some implementations, a thickness of the AlGaN layer 110 is in a range of 10 nm to 30 nm (e.g., 20 nm). A thickness of the second unintentionally doped GaN layer 112 is typically in a range of 1 nm to 10 nm (e.g., 5 nm). In some cases, a thickness of the p-GaN layer 114 is in a range of 50 nm to 150 nm (e.g., 90 nm). A concentration of the Mg in the p-GaN layer 114 is typically in a range of 1×10¹⁸ to 1×10²⁰ cm⁻³ (e.g., 1×10¹⁹ cm⁻³). A surface of the p-GaN layer 114 in contact with the anode 118 has alternating regions of activated and passivated p-GaN (e.g., stripe-shaped structure under the anode 118).

Fabricating the H-GAT design includes exposing the hydrogen plasma to the p-GaN layer 114 outside the circular element 120 (e.g., highly resistive), while the p-GaN inside the circular element 120 remains activated, which can be identified in a scanning electron microscope (SEM) image, as shown in FIGS. 1C and 1D. An example of suitable distances (e.g., R_{T}, S_{T}, D_{T}, and L_{A}) are shown in FIG. 1D.

The stripe-shaped termination is typically introduced in the H-GAT structure to further alleviate electric field crowding at the edge of the anode 118. The width of the stripe shape is typically in a range of 0.1 μm to 5 μm (e.g., 0.5 μm), and the distance between each stripe is typically in a range of 0.1 μm to 5 μm (e.g., 0.75 μm).

This design can promote the distribution of the crowded electric field at the edge of an anode to the whole surface between an anode and a cathode at a high reverse bias. FIG. 1B is a schematic diagram of an example Schottky barrier diode fabricate without a H-GAT design (e.g., the p-GaN layer without patterns was passivated by the hydrogen plasma process).

### EXAMPLES

Device epilayers were grown by metal-organic chemical vapor deposition (MOCVD) on a SiC substrate, including a thick GaN buffer layer, a 300 nm unintentionally doped-GaN layer, a 1 nm AlN space layer, a 20 nm Al_{0.2}Ga_{0.8}N layer, a 5 nm unintentionally doped-GaN space layer, and a 90 nm p-GaN layer with an acceptor Mg concentration of 1×10¹⁹ cm⁻³. An epilayer is a layer of material that is grown on a substrate through epitaxy. Epitaxy involves depositing a layer such that the crystal lattice of the deposited layer aligns with the lattice of the underlying substrate or layer. Hall measurement of the AlGaN/GaN epilayers revealed a 2DEG mobility (μ_{2DEG}) of 1200 cm²/V·s and a 2DEG density (n_{2DEG}) of 8×10¹² cm⁻², corresponding to a sheet resistance R_{SH} of 650 Ω/sq at room temperature. The sample was annealed in a nitrogen atmosphere at 800° C. for 30 minutes to activate the p-GaN layer. For the device fabrication, the devices were first isolated by low-power Cl₂ reactive ion etching, followed by 20% TMAH treatment at 90° C. to recover the etching damage. Then, the metal stack Ti/Al/Ni/Au was deposited as the device cathode, followed by post-annealing at 850° C. for 30 seconds. The p-GaN layer on the cathode was etched before metal deposition for better ohmic contact. Then, low-power hydrogen plasma was generated in an inductively coupled plasma etching tool with an inductively coupled plasma power of 300 W and RF power of 5 W and applied on the surface with a nickel hard mask, followed by annealing at 500° C. for the formation of the Mg—H complex. Finally, the anode metal Ni/Au was deposited. The device without hydrogen plasma-based guard array termination (H-GAT) was also fabricated at the same time for comparison. For the device measurements, the forward current-voltage (I-V) and C-V curves were measured using Keithley 4200 SCS semiconductor analyzer. Reverse I-V curves were measured using Keysight B1505A power device analyzer/curve tracer (up to 3 kV). The breakdown voltages were assessed using a high-voltage power supply by Matsuada (30 kV capability) at room temperature.

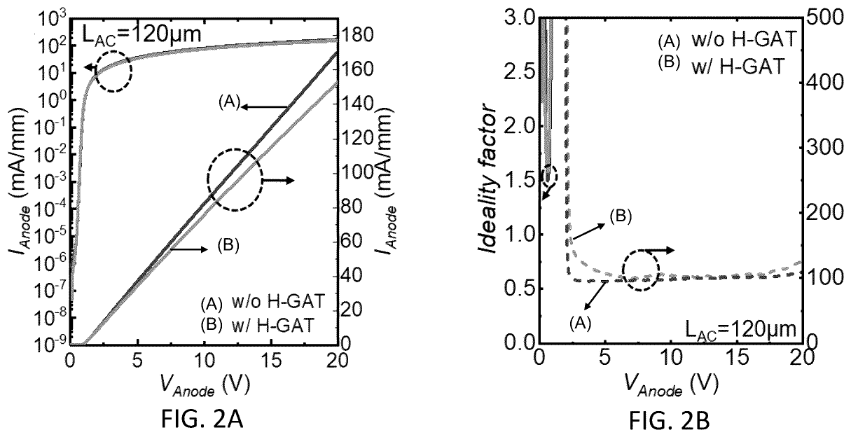

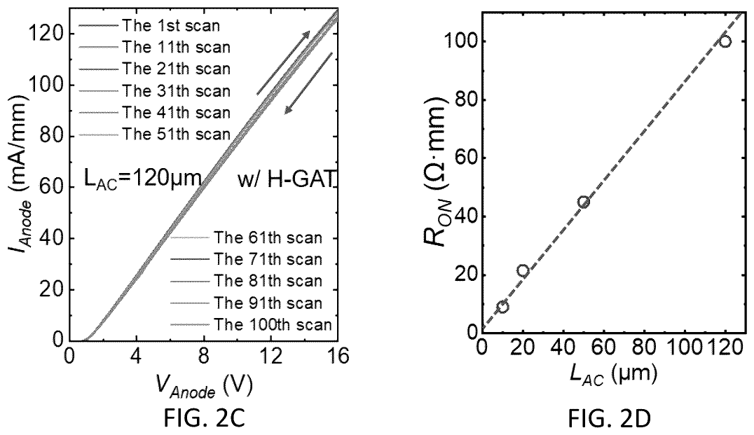

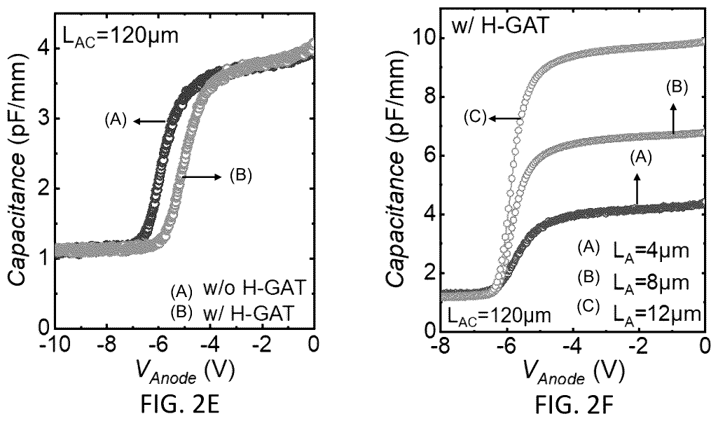

The forward I-V curves of the AlGaN/GaN heterojunction Schottky barrier diodes (L_{AC}=120 μm) with and without H-GAT are shown in FIG. 2A. The two devices had a turn-on voltage of 1.1 V and an on/off ratio of 10⁹-10¹⁰ at ±10V. The device with H-GAT had a current degradation of ˜15% at 20 V compared with the device without H-GAT. FIG. 2B shows the extracted ideality factor of the two devices. The device with or without H-GAT had an ideality factor of ˜1.5. FIG. 2C shows 100 cycles of forward and backward I-V scans of the device with H-GAT. The overlap among the scans indicates good stability of the device under forward bias. The extracted specific on-resistance (R_{ON}) vs. L_{AC} is shown in FIG. 2D, indicating that the channel resistance dominates in the device R_{ON} with negligible contact resistance. FIG. 2E shows the C-V characteristics of the device (L_{AC}=120μm) with or without H-GAT. The curves of the device with H-GAT shifted to the right compared with the device without H-GAT due at least in part to the electron consumption in the 2DEG channel by the activated p-GaN. The device with or without H-GAT had a similar capacitance at zero bias (Cⱼ₀) of ˜4.2 pF/mm. This can be due at least in part to the floating structure design of termination, lower 2DEG density, and short L_{A}. The C-V curves of the device (L_{AC}=120 μm) with different L_{A} are shown in FIG. 2F. The Cⱼ₀ increased from 4.2 to 6.8 and 10 with the LA increasing from 4 μm to 8 and 12 μm. Negligible difference in Cⱼ₀ was observed with different L_{AC}. A shorter L_{A} could benefit the device frequency performance but reduce the breakdown voltage without H-GAT. The Cⱼ₀ and cutoff frequency (f_{c}) of the device with different L_{AC} was calculated from equation f_{c}=1/(2πCⱼ₀R_{ON}), and the width of the device was set to 100 μm. The devices had a f_{c} of 8.4, 3.6, 1.5, and 0.8 GHz with increasing L_{AC} from 10, 20, 50, to 120 μm, respectively.

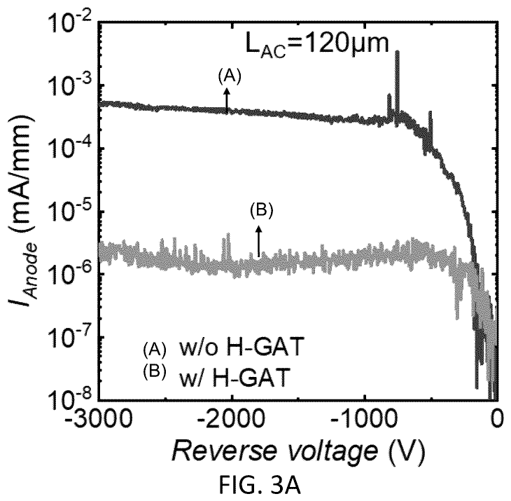

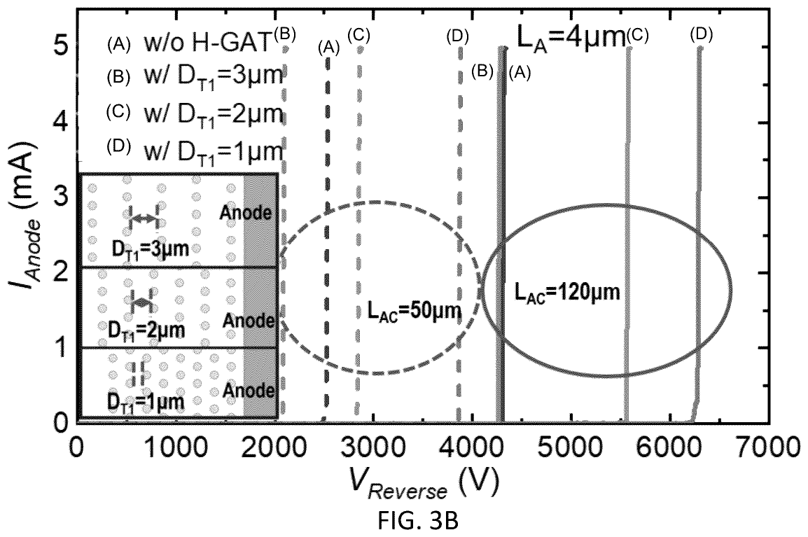

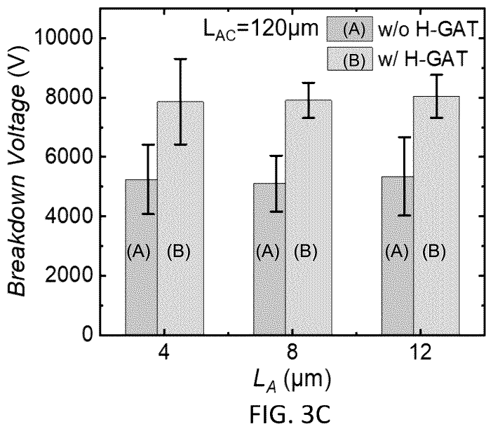

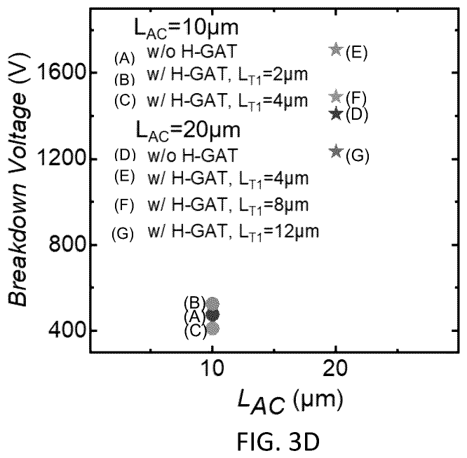

FIG. 3A shows the reverse I-V curve of the AlGaN/GaN heterojunction Schottky barrier diodes (L_{AC}=120 μm) with and without H-GAT up to 3 kV. While the setup with 3 kV capability has a good current resolution, the setup with 30 kV capability has a lower current resolution due at least in part to compliance limit. The device with H-GAT showed low leakage current level of 10⁻⁵-10⁻⁶ mA/mm at a reverse voltage of 3 kV. FIG. 3B shows the breakdown voltage performance of the devices with or without H-GAT (T₁ only) at different parameters D_{T1} from 3 μm to 1 um (shown in the insert), where the device with a smaller D_{T1} had a higher BV. FIG. 3C shows the breakdown voltages of the device (L_{AC}=120 μm) with or without H-GAT. Compared with the device without H-GAT, the device with H-GAT termination structure showed larger breakdown voltage with a highest breakdown voltage of 9.5 kV. It was also observed that the L_{A} had negligible impact on the BV, as also confirmed by electric field simulations. FIG. 3D shows the breakdown voltage performance of the L_{AC}=10 and 20 μm device. The device breakdown voltage decreased with increasing L_{T1} due at least in part to enhanced electric field crowding at the edge of the termination.

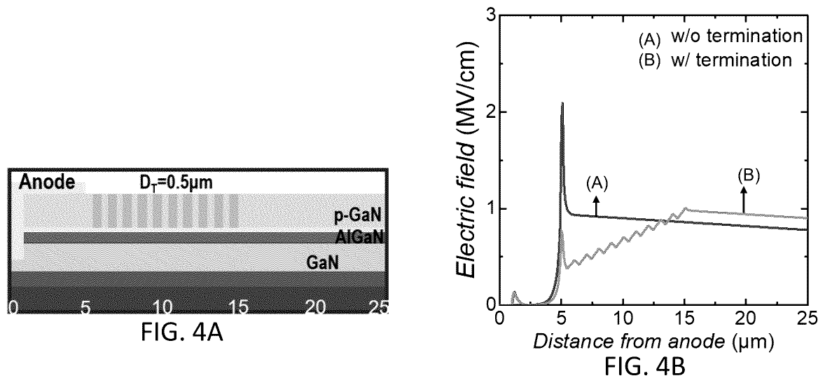

A technology computer-aided design (TCAD) Silvaco software was used to simulate the electric field distribution of the devices with a series of floating p-GaN terminations, as shown in FIG. 4A. A series of p-GaN terminations was used to model the circle array structure at a macro level. FIG. 4B shows the electric field distribution at −2500 V extracted from the cutlines in electric field mappings. With the array structure of p-GaN termination, the crowded electric field at the edge of the anode was mitigated.

Although this disclosure contains many specific embodiment details, these should not be construed as limitations on the scope of the subject matter or on the scope of what may be claimed, but rather as descriptions of features that may be specific to particular embodiments. Certain features that are described in this disclosure in the context of separate embodiments can also be implemented, in combination, in a single embodiment. Conversely, various features that are described in the context of a single embodiment can also be implemented in multiple embodiments, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

What is claimed is:

1. A Schottky barrier diode comprising:
a SiC substrate;
a GaN buffer layer;
a first unintentionally doped GaN layer;
an AlN layer;
an AlGaN layer;
a second unintentionally doped GaN layer;
a p-GaN layer, wherein the p-GaN layer is doped with Mg; and
a cathode and an anode, each in direct contact with the first unintentionally doped GaN layer, the AlN layer, the AlGaN layer, the second unintentionally doped GaN layer, and the p-GaN layer, wherein the anode has a length L_{A} along the p-GaN layer, the cathode has a length L_{C} along the p-GaN layer, and the anode and the cathode are separated by a distance L_{AC} along the p-GaN layer,
wherein an outer surface of the p-GaN layer defines n portions, each portion having a length L_{Tn} extending along the p-GaN layer between the cathode and the anode and defining an array Tₙ of activated p-GaN regions, and each element in array Tₙ is separated by a passivated p-GaN region.

2. The Schottky barrier diode of claim 1, wherein each element in each array Tₙ is a circular element, each circular element in each array Tₙ has a diameter R_{Tn}, and each R_{Tn} is independently in a range of 0.5 μm to 1 μm.

3. The Schottky barrier diode of claim 2, wherein each circular element in each array Tₙ is arranged in a row, and each row is separated from an adjacent row in array Tₙ by distance D_{Tn}.

4. The Schottky barrier diode of claim 2, where each circular element in each array Tₙ is separated from other circular elements in array Tₙ by distance S_{Tn}.

5. The Schottky barrier diode of claim 1, wherein n=3.

6. The Schottky barrier diode of claim 5, wherein array T₁ is positioned closer to the anode, array T₃ is positioned closer to the cathode, and array T₂ is positioned between array T₁ and array T₃.

7. The Schottky barrier diode of claim 6, wherein each L_{Tn} is in a range of 10 μm to 60 μm.

8. The Schottky barrier diode of claim 6, wherein L₃>L₂>L₁.

9. The Schottky barrier diode of claim 6, wherein each S_{Tn} is in a range of 0.1 μm to 5 μm.

10. The Schottky barrier diode of claim 6, wherein S_{T3}>S_{T2}>S_{T1}.

11. The Schottky barrier diode of claim 6, wherein each D_{Tn} is in a range of 0.1 μm to 5 μm.

12. The Schottky barrier diode of claim 6, wherein D_{T3}>D_{T2}>D_{T1}.

13. The Schottky barrier diode of claim 1, wherein L_{AC} is in a range of 5 μm to 150 μm.

14. The Schottky barrier diode of claim 1, wherein L_{A} is in a range of 1 μm to 15 μm.

15. The Schottky barrier diode of claim 1, wherein a thickness of the first unintentionally doped GaN layer is in a range of 200 nm to 400 nm.

16. The Schottky barrier diode of claim 1, wherein a thickness of the AlN layer is in a range of about 0.1 nm to about 5 nm, a thickness of the AlGaN layer is in a range of 10 nm to 30 nm, and a thickness of the second unintentionally doped GaN layer is in a range of 1 nm to 10 nm.

17. The Schottky barrier diode of claim 1, wherein a thickness of the p-GaN layer is in a range of 50 nm to 150 nm.

18. The Schottky barrier diode of claim 1, wherein a concentration of the Mg in the p-GaN layer is in a range of 1×10¹⁸ to 1×10²⁰ cm⁻³.

19. The Schottky barrier diode of claim 1, wherein a surface of the p-GaN layer in contact with the anode has alternating regions of activated and passivated p-GaN.

20. A method of fabricating a Schottky barrier diode, the method comprising:
growing a plurality of epilayers by metal-organic vapor deposition on a SiC substrate in the following sequence to yield a device:
a GaN buffer layer;
a first unintentionally doped GaN layer;
an AlN layer;
an AlGaN layer;
a second unintentionally doped GaN layer; and
a p-GaN layer, wherein the p-GaN layer is doped with Mg;
annealing the device to activate the p-GaN layer;
depositing a cathode on the device;
masking selected portions of the device;
exposing the device to a hydrogen plasma;
annealing the device, thereby bonding hydrogen atoms to at least some of the Mg; and
depositing an anode on the device.
